(19) United States
(12) Patent Application Publication
(10) Pub. No.: US 2002/0167089 A1
(43) Pub. Date: Nov. 14, 2002

(54) Copper dual damascene interconnect technology

(75) Inventors: Kie Y. Ahn, Chappaqua, NY (US); Leonard Forbes, Corvallis, OR (US)

Correspondence Address: Schwegman, Lundberg, Woessner & Kluth, P.A., Attn: Edward J. Brooks, III, P.O. Box 2938, Minneapolis, MN, 55402, US

(73) Assignee: Micron Technology, Inc.

(21) Appl. No.: 09/854,540

(22) Filed: May 14, 2001

(51) Int. Cl. H01L 21/44; H01L 23/48

(52) U.S. Cl. 257/762; 438/687; 257/764; 438/648; 257/774

(57) ABSTRACT

A process and structure for copper damascene interconnects including a tungsten-nitride (WN₂) barrier layer formed by atomic layer deposition is disclosed. The process method includes of forming a copper damascene structure by forming a first opening through a first insulating layer. A second opening is formed through a second insulating layer which is provided over the first insulating layer. The first opening being in communication with the second opening. A tungsten-nitride (WN₂) layer is formed in contact with the first and second openings. And, a copper layer is provided in the first and second openings. Copper is selectively deposited by a CVD process and/or by an electroless deposition technique at low temperature to provide improved interconnects having lower electrical resistivity and more electro/stress-migration resistance than conventional interconnects. Additionally, metal adhesion to the underlying substrate materials is improved and the amount of associated waste disposal problems is reduced.

### FIELD OF THE INVENTION

The present invention relates to the field of semiconductors and, in particular, to a method of forming damascene structures in semiconductor devices.

### BACKGROUND OF THE INVENTION

The integration of a large number of components on a single integrated circuit (IC) chip requires complex interconnects. Ideally, the interconnect structures should be fabricated with minimal signal delay and optimal packing density. The reliability and performance of integrated circuits may be affected by the quality of their interconnect structures. Advanced multiple metallization layers have been used to accommodate higher packing densities as devices shrink below sub-0.25 micron design rules. One such metallization scheme is a dual damascene structure formed by a dual damascene process. The dual damascene process is a two-step sequential mask/etch process to form a two-level structure, such as a via connected to a metal line situated above the via.

FIGS. 1A-1C illustrate a sequence of fabrication steps for a known dual damascene process as applied to interconnect formation. As shown in FIG. 1A, the process begins with the deposition of a first insulating layer 140 over a first level interconnect metal layer 120, which in turn is formed over or within a semiconductor substrate 100. A second insulating layer 160 is next formed over the first insulating layer 140. An etch stop layer 150 is typically formed between the first and second insulating layers 140, 160. The second insulating layer 160 is patterned by photolithography with a first mask (not shown) to form a trench 170 corresponding to a metal line of a second level interconnect. The etch stop layer 150 prevents the upper level trench pattern 170 from being etched through to the first insulating layer 140.

As illustrated in FIG. 1B, a second masking step followed by an etch step are applied to form a via 180 through the etch stop layer 150 and the first insulating layer 140. After the etching is completed, both the trench 170 and the via 180 are filled with metal 122, which is typically copper (Cu), to form a damascene structure 125, as illustrated in FIG. 1C.

If desired, a second etch stop layer (not shown) may be formed between the substrate 100 and the first insulating layer 140 during the formation of the dual damascene structure 125. In any event, and in contrast to a single damascene process, the via and the trench are simultaneously filled with metal. Thus, compared to the single damascene process, the dual damascene process offers the advantage of process simplification and low manufacturing cost.

In an attempt to improve the performance, reliability and density of the interconnects, the microelectronics industry has recently begun migrating away from the use of aluminum (Al) and/or its alloys for the interconnects. As such, advanced dual damascene processes have begun using copper (Cu) as the material of choice because copper has high conductivity, extremely low resistivity (about 1.7 μΩcm) and good resistance to electromigration. Unfortunately, copper diffuses rapidly through silicon dioxide (SiO₂) or other interlayer dielectrics, such as polyimides and parylenes, and copper diffusion can destroy active devices, such as transistors and capacitors, formed in the IC substrate. In addition, metal adhesion to the underlying substrate materials must be excellent to form reliable interconnect structures but the adhesion of copper to interlayer dielectrics, particularly to SiO₂, is generally poor.

The introduction of copper conductors in integrated circuits has recently received wide publicity. As mentioned above, copper interconnect is the most promising metallization scheme for the future generation high-speed ULSI, primarily because of lower electrical resistivity (1.7 vs. 2.3 μΩcm) and electro/stress-migration resistance than the conventional aluminum-based materials. Recently, IBM and Motorola introduced full, 6-level copper wiring in a sub-0.25 μm CMOS ULSI technology (D. Edelstein, et al., “Full Copper Wiring in a sub-0.25 μm CMOS ULSI technology”, Technical Digest of 1997 IEDM, p. 773-776 (1997); S. Vankatesan, et al., “A High Performance 1.8 v, 0.2 μm CMOS Technology with Copper Metallization”, ibid, p. 769-772); J. G. Ryan, et al., “Copper Interconnects for Advanced Logic and DRAM”, Extended Abstracts of the 1998 International Conference on Solid State Devices and Materials, p. 258-259 (1998)). Again, however, as mentioned above copper atoms easily diffuse into silicon device, and act as recombination centers and spoil device performance. Copper also diffuses into commonly used dielectric materials SiO₂ and certain polymers. As a result, in order to adopt copper interconnects for ULSI, a suitable diffusion barrier is needed.

Finally, as mentioned above, of the several schemes proposed for fabricating copper interconnects, the most promising method appears to be the Damascene process shown in FIGS. 1A-C. Using this method, the trenches for conductors and vias are patterned in blanket dielectrics, and then the desired metal is deposited into the trenches and holes in one step. Chemical mechanical polishing (CMP) is used to remove the unwanted surface metal, while leaving the desired metal in the trenches and holes. This leaves a planarized surface for subsequent metallization to build multi-level interconnect. Unfortunately, this technology not only uses a large amount of expensive consumables for the CMP process and the associated waste disposal problem, but also is a very wasteful copper process. Typically, the conductors and via holes in the given metallization level occupies only a few percent, and the bulk of the deposited thick high-purity copper is removed by polishing operation, and becomes very expensive.

Accordingly, there is a need for an improved damascene process which reduces production costs and increases productivity. There is also a need for a method of increasing the adhesion of copper to underlying damascene layers as well as a method of decreasing copper diffusion in such layers.

### SUMMARY OF THE INVENTION

The present invention provides a method for fabricating a copper damascene interconnect structure in a semiconductor device which requires fewer processing steps and reduces the diffusion of copper atoms to underlying damascene layers, improves metal adhesion to the underlying substrate materials, and reduces the amount of associated waste disposal problems.

In one embodiment of the present invention, a process and structure for copper damascene interconnects including a tungsten-nitride (WN₂) barrier layer formed by atomic layer deposition is disclosed. The process method includes of forming a copper damascene structure by forming a first opening through a first insulating layer. A second opening is formed through a second insulating layer which is provided over the first insulating layer. The first opening being in communication with the second opening. A tungsten-nitride (WN₂) layer is formed in contact with the first and second openings. Hence, trenches and vias are formed according to damascene processing, subsequent to which a thin tungsten-nitride (WN₂) diffusion barrier layer is formed by an atomic layer deposition inside the trenches and vias. A copper layer is provided in the first and second openings. Copper is selectively deposited by a CVD process and/or by an electroless deposition technique at low temperature to provide improved interconnects having lower electrical resistivity and more electro/stress-migration resistance than conventional interconnects. Additionally, the adhesion of copper atoms to the underlying layers is increased, while the diffusion of copper atoms into adjacent interconnect layers is suppressed and the amount of associated waste disposal problems is reduced.

Additional advantages of the present invention will be more apparent from the detailed description and accompanying drawings, which illustrate preferred embodiments of the invention.

### BRIEF DESCRIPTION OF THE DRAWINGS

FIG. 1A is a cross-sectional view of a conventional dual damascene formation process for a semiconductor device at a preliminary stage of production.

FIG. 1B is a cross-sectional view of the semiconductor device of FIG. 1A at a subsequent stage of production.

FIG. 1C is a cross-sectional view of the semiconductor device of FIG. 1B at a subsequent stage of production.

FIGS. 2A-2K are cross-sectional views illustrating a sequence of fabrication steps for forming a dual damascene copper interconnect in association with a semiconductor device according to the teachings of the present invention.

FIGS. 3A-3B are cross-sectional views illustrating a sequence of fabrication steps for forming a dual damascene copper interconnect in association with a semiconductor device in accordance with a second embodiment of the present invention.

FIG. 4 is a cross-sectional view of a multilayer damascene copper interconnect in association with a semiconductor device constructed in accordance with a third embodiment of the present invention.

FIG. 5 illustrates an electronic system having a memory cell with a copper damascene structure according to the present invention.

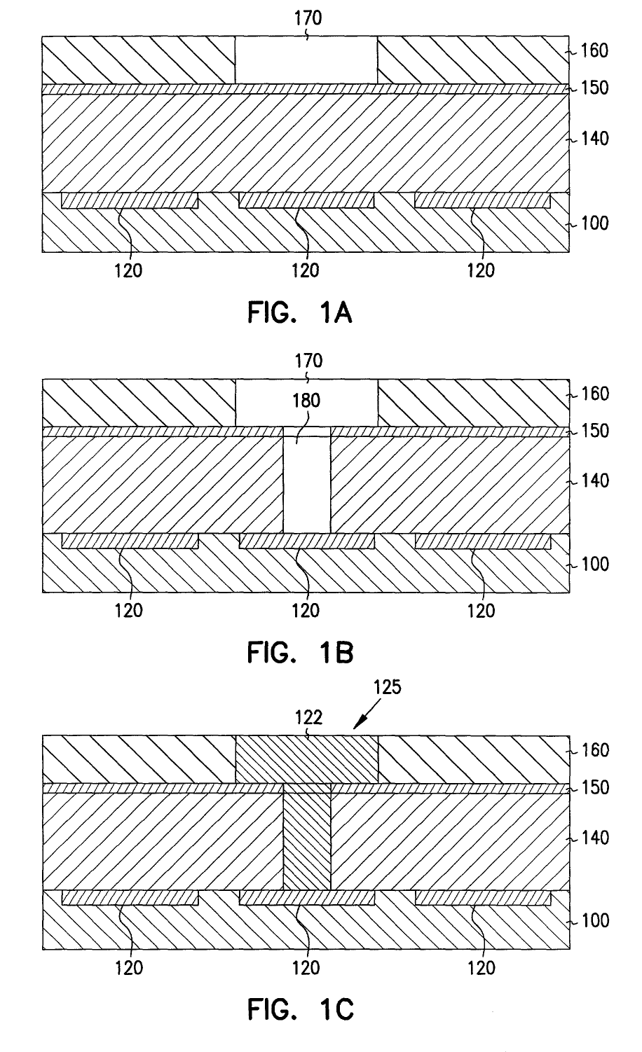

### DETAILED DESCRIPTION

In the following detailed description, reference is made to various specific embodiments in which the invention may be practiced. These embodiments are described with sufficient detail to enable those skilled in the art to practice the invention, and it is to be understood that other embodiments may be employed, and that structural and electrical changes may be made without departing from the spirit or scope of the present invention.

The term “substrate” used in the following description may include any semiconductor-based structure that has a semiconductor surface. The term should be understood to include silicon, silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to a “substrate” in the following description, previous process steps may have been utilized to form regions or junctions in or on the base semiconductor or foundation.

The term “copper” is intended to include not only elemental copper, but also copper with other trace metals or in various alloyed combinations with other metals as known in the art, as long as such alloy retains the physical and chemical properties of copper. The term “copper” is also intended to include conductive oxides of copper.

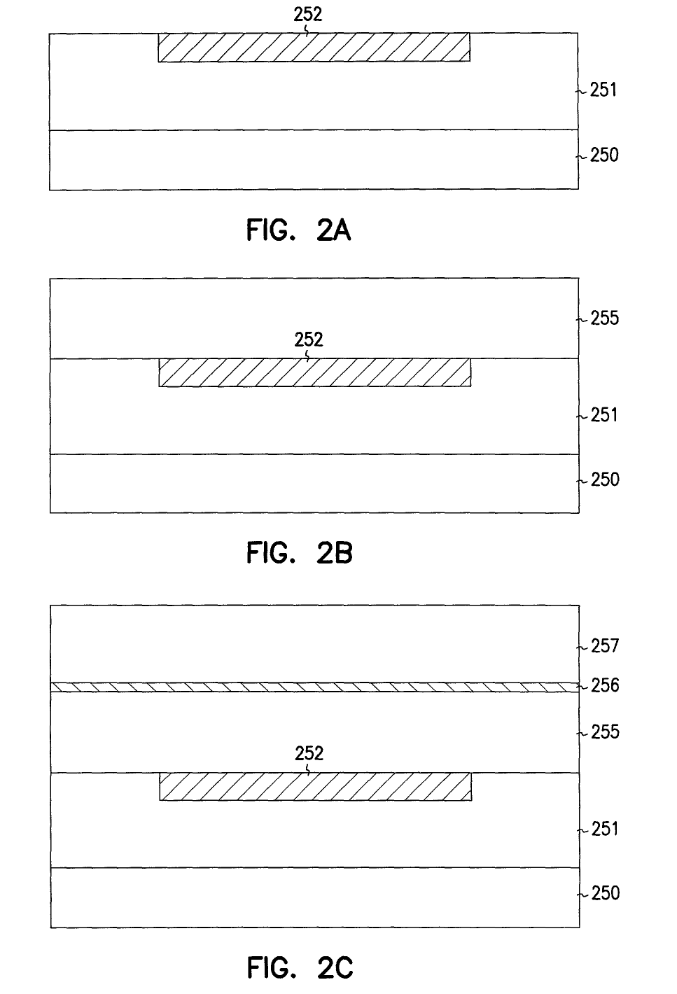

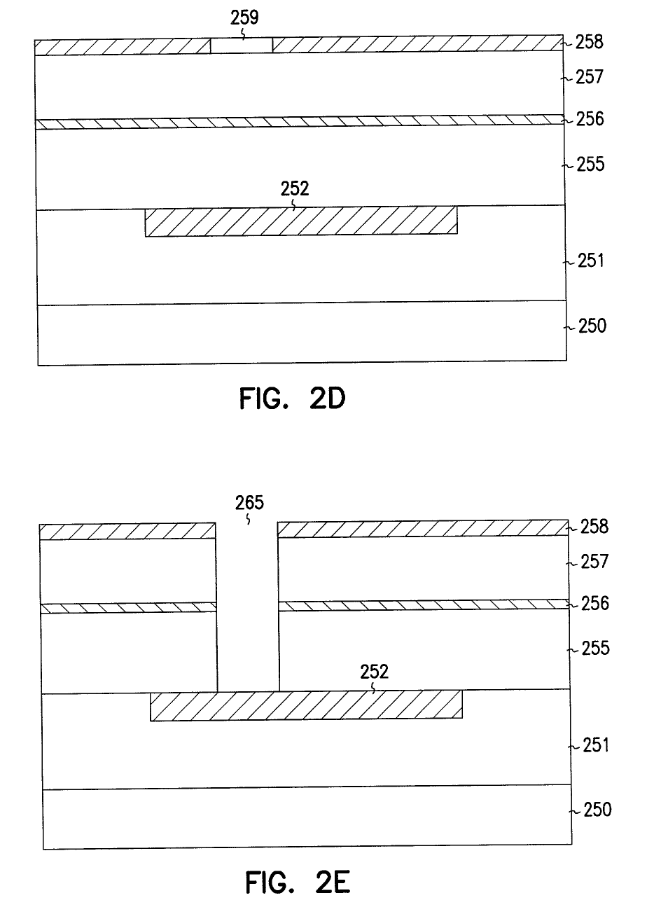

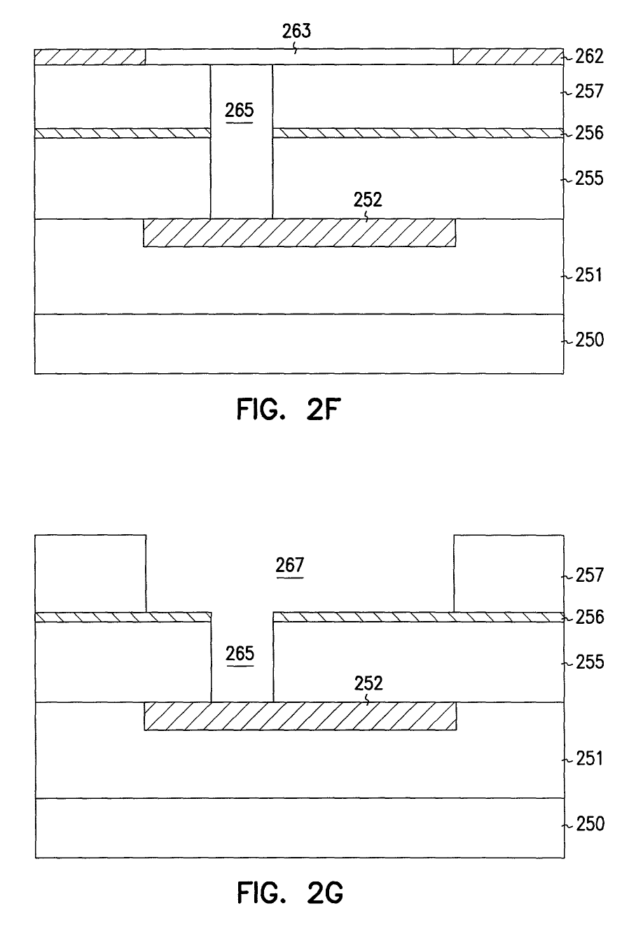

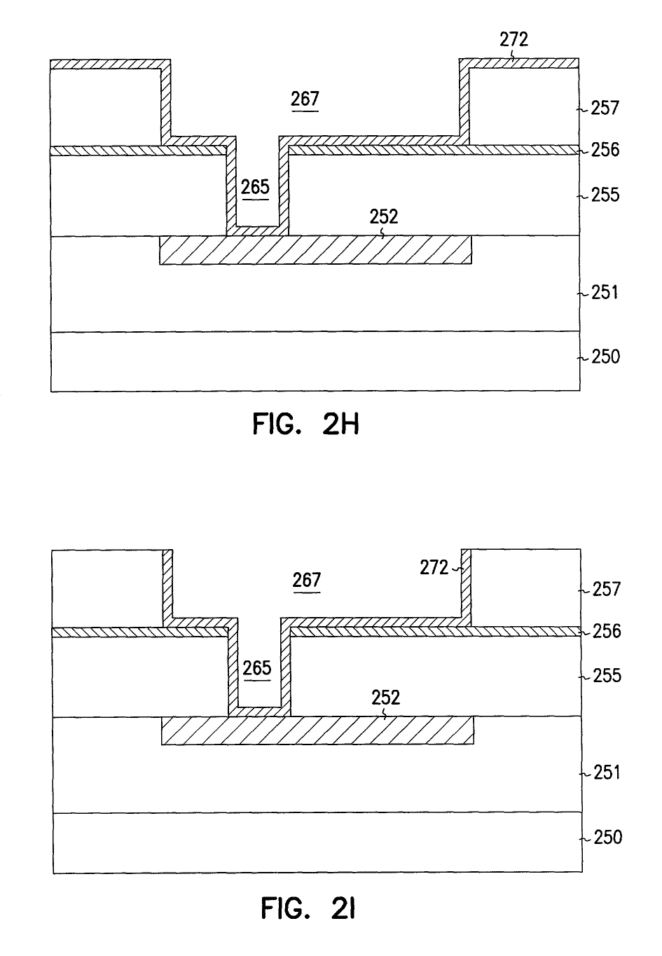

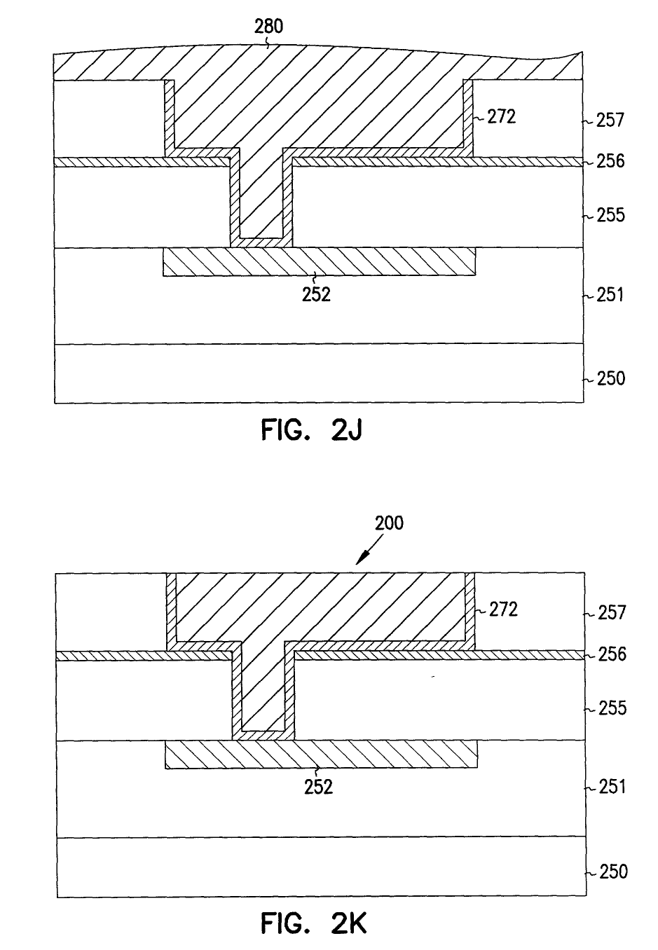

FIGS. 2A-2K are cross-sectional views illustrating a sequence of fabrication steps for forming a dual damascene copper interconnect in association with a semiconductor device according to the teachings of the present invention. FIG. 2A depicts a portion of an insulating layer 251 formed over a semiconductor substrate 250, on or within which a metal layer 252 has been formed. The metal layer 252 represents a lower metal interconnect layer which is to be later interconnected with an upper copper interconnect layer. The metal layer 252 may for formed of copper (Cu), but other conductive materials, such as tungsten (W) or aluminum (Al) and their alloys, may be used also.

FIG. 2B illustrates the structure following the next series of processing steps. As shown in FIG. 5, a first intermetal insulating layer 255 is formed overlying the insulating layer 251 and the metal layer 252. In an exemplary embodiment of the present invention, the first intermetal insulating layer 255 is blanket deposited by spin coating to a thickness of about 2,000 Angstroms to 15,000 Angstroms, more preferably of about 6,000 Angstroms to 10,000 Angstroms. The first intermetal insulating layer 255 may be cured at a predefined temperature, depending on the nature of the material. Other known deposition methods, such as sputtering by chemical vapor deposition (CVD), plasma enhanced CVD (PECVD), or physical vapor deposition (PVD), may be used also for the formation of the first intermetal insulating layer 255, as desired.

In one embodiment, the first intermetal insulating layer 255 is be formed of a conventional insulating oxide, such as silicon oxide (SiO₂). In alternative embodiments, the first intermetal insulating layer 255 is formed of a low dielectric constant material such as, for example, polyimide, spin-on-polymers (SOP), parylene, flare, polyarylethers, polytetrafluoroethylene, benzocyclobutene (BCB), SILK, fluorinated silicon oxide (FSG), NANOGLASS or hydrogen silsesquioxane, among others. The present invention is not limited, however, to the above-listed materials and other insulating and/or dielectric materials known in the industry may be used also.

FIG. 2C illustrates the structure following the next series of processing steps. As shown in FIG. 2C, a second intermetal insulating layer 257 is formed overlying an etch stop layer 256 and below a copper metal layer that will be formed subsequently. According to the teachings of the present invention, the second intermetal insulating layer 257 can be formed, for example, by deposition to a thickness of about 2,000 Angstroms to about 15,000 Angstroms, more preferably of about 6,000 Angstroms to 10,000 Angstroms. Other deposition methods, such as the ones mentioned above with reference to the formation of the first intermetal insulating layer 255 can also be used. The second intermetal insulating layer 257 can be formed of the same material used for the formation of the first intermetal insulating layer 255 or a different material. The etch stop layer 256 can be formed of conventional materials such as silicon nitride (Si₃N₄) for example.

FIG. 2D illustrates the structure following the next series of processing steps. As shown in FIG. 2D, a first photoresist layer 258 is formed over the second intermetal insulating layer 257 to a thickness of about 2,000 Angstroms to about 3,000 Angstroms. The first photoresist layer 258 is then patterned with a mask (not shown) having images of a via pattern 259. Thus, as shown in FIG. 2E, a via 265 can be formed by first etching through the photoresist layer 258 and into the second intermetal insulating layer 257 with a first etchant, and subsequently etching into the first intermetal insulating layer 255 with a second etchant. As one of ordinary skill in the art will understand upon reading this disclosure, the etchants (not shown) can be selected in accordance with the characteristics of the first and second insulating materials 255, 257, so that the insulating materials are selectively etched until the second etchant reaches the metal layer 252.

After the formation of the via 265 through the second and first intermetal insulating layers 257, 255, a trench 267 is formed by photolithography techniques as shown in FIG. 2G. As such, a second photoresist layer 262, as shown in FIG. 2E, is formed over the second intermetal insulating layer 257 to a thickness of about 2,000 Angstroms to about 3,000 Angstroms and then patterned with a mask (not shown) having images of a trench pattern 263. According to the teachings of the present invention, the trench pattern 263 is then etched into the second intermetal insulating layer 257 using photoresist layer 262 as a mask to form trench 267, as shown in FIG. 2G. The thickness of the first intermetal insulating layer 255 defines the depth of the via 265, as shown in FIGS. 2E-2G. The thickness of the second intermetal insulating layer 257 defines the depth of the trench 267 of FIG. 2G.

The etching of the trench 267 may be accomplished using the same etchant employed to form the via 265, as shown in FIG. 2E, or a different etchant.

Subsequent to the formation of trench 267, the second photoresist layer 262 is removed so that further steps to create the copper dual damascene structure 200, shown in FIG. 2K, may be carried out.

FIG. 2H illustrates the structure following the next sequence of fabrication steps. As shown in FIG. 2H, a diffusion barrier layer 272 is formed on the via 265 and the trench 267 to a thickness of about 50 Angstroms to about 200 Angstroms, more preferably of about 100 Angstroms.

In one embodiment according to the teachings of the present invention, the diffusion barrier layer 272 is formed of tungsten-nitride (WN₂) by atomic layer deposition. One example of a method for tungsten-nitride (WN₂) by atomic layer deposition is described in an article by Krause, J. W. et al. entitled, “Atomic layer deposition of tungsten nitride films using sequential surface reaction”, Journal of Electrochemical Soc., 147:3, 1175-81 (2000). According to the teachings of the invention, a thin layer of WN₂ prepared by ALD is used as the diffusion barrier layer in building copper interconnects for semiconductor devices. According to one embodiment of the invention, the deposition of the tungsten nitride film as the diffusion barrier layer 272 is performed at a temperature of about 600 to 800 degrees Kelvin. In one embodiment according to the teachings of the present invention, a tungsten-nitride (WN₂) layer is formed as the diffusion barrier layer 272 such that the diffusion barrier layer 272 is less than five atomic layers thick. According to the teachings of the present invention, these atomic layers are so uniform that a vertical wall as well as a short side wall obtain an equal thickness. In these embodiments, x-ray photoelectron spectroscopy depth profiling experiments evidence that the film diffusion barrier layer 272 has a WN₂ stoichiometry with low C and O impurity concentrations. Further, x-ray diffraction investigation reveals that the tungsten nitride films serving as the diffusion barrier layer 272 are micro-crystalline. Atomic force microscopy measurements of the deposited film serving as the diffusion barrier layer 272 evidence a remarkably flat surface indicating smooth film growth for the diffusion barrier layer 272.

In one embodiment of the invention, the tungsten-nitride (WN₂) diffusion barrier layer 272 is simultaneously deposited in both the via 265 and the trench 267. However, the invention is not limited to this embodiment. Thus, in an alternative embodiment, the tungsten-nitride (WN₂) diffusion barrier layer 272 is deposited first in the via 265 before the formation of the trench 267, and then in the trench 267 after its respective formation. According to the teachings of the present invention, in the case of either embodiment, after the formation of the diffusion barrier layer 272, horizontal portions of the tungsten-nitride (WN₂) material, serving as the diffusion barrier layer 272, which formed above a top surface of the second insulating material 257 are removed by either an etching or a polishing technique to form the structure illustrated in FIG. 2I. In one embodiment according to the teachings of the present invention, chemical mechanical polishing (CMP) is used to polish away excess tungsten-nitride (WN₂) material above the second insulating material 257 and the trench 267 level. According to the teachings of the present invention, the second insulating material 257 acts as a polishing stop layer when CMP is used.

FIG. 2J illustrates the structure following the next sequence of fabrication steps. As shown in FIG. 2J, a conductive material 280 comprising copper (Cu) is deposited to fill in both the via 265 and the trench 267. In one embodiment according to the teachings of the present invention, the copper is selectively deposited by chemical vapor deposition (CVD) at a low temperature. Some examples of methods for selective deposition of copper by CVD at low temperature are described in an article by Kaloyeros et al., entitled “Blanket and Selective Copper CVD From Cu(fod)₂ For Multilevel Metallization, Mat. Res. Soc. Symp. Proc., Vol 181 (1990), and in an article by Eisenbraun et al., entitled “Selective and Blanket Low-Temperature Copper CVD for Multilevel Metallization”, Materials Research Society Conference Proceedings, ULSI-VII, 397-401 (1992), the disclosures of which are incorporated by reference herein. In one embodiment according to the teachings of the present invention, copper films are deposited by selective CVD at temperature of about 300-400° Celsius in an atmosphere of pure H₂ from the β-diketonate precursor bis (6,6,7,8,8,8-heptafluoro-2,2-dimethyl 1-3,5-octanedino) copper (II), Cu(fod)₂. In an alternative embodiment according to the teachings of the present invention, copper films are deposited by selective CVD at temperature of about 300-400° Celsius in an atmosphere of pure or Ar from the β-diketonate precursor bis (6,6,7,8,8,8-heptafluoro-2,2-dimethyl 1-3,5-octanedino) copper (II), Cu(fod)₂. According to the teachings of the present invention, the reactor is first pumped down to a base pressure of less than 5×10⁻⁷ torr. Then the source compound is introduced into the sublimator which is heated to between 40 and 75° Celsius. A mass flow controller is employed to control the flow of the mixed gas-precursor into the reactor. Deposition is carried out using argon and hydrogen as carrier gases. According to the teachings of the present invention, the substrates are heated from 300 to 400° Celsius. The pressure during deposition ranges between 1 and 10 torr, and gas flow ranges from 30 to 55 sccm.

Since the temperatures involved in the embodiments of the present invention are relatively low, any low-k dielectric material including polymers, which can withstand the above temperature range (300-400° C.), can be readily used with this technology as interlayer dielectrics, e.g. the first and second insulating materials 255, 257.

FIG. 2K illustrates the structure following the next sequence of fabrication steps. According to the teachings of the present invention, as shown in FIG. 2K, after the deposition of the copper material 280, excess copper formed above the surface of the second insulating material 257 may be removed by either an etching or a polishing technique to form the copper dual damascene structure 200. In one embodiment of the present invention, chemical mechanical polishing (CMP) is used as the technique to polish away excess copper above the second insulating material 257 and the trench 267 level. In this manner, the second insulating material 257 acts as a polishing stop layer when CMP is used.

As one of ordinary skill in the art will understand upon reading this disclosure, the above described embodiments for selectively depositing copper 280 by chemical vapor deposition (CVD) at a low temperature, according to the teachings of the present invention, helps to reduce the amount of wasted copper in the process.

According to the teachings of the present invention, the selective deposition of copper by CVD described above is not the only method that can be employed for forming the conductive material 280. According to another embodiment of the invention, copper can be selectively deposited by an electroless plating technique. In some instance, an electroless plating technique is more attractive than conventional electroplating methods. For example, in some embodiments electroless plating is more advantageous than electroplating because of the low cost of tools and materials. An example of a studies for electroless plating is provided in an article by Shacham-Diamand et al. entitled “Copper electroless deposition technology for ultra-large-scale-integration (ULSI) metallization,” Microelectronic Engineering, Vol. 33, pp. 47-48 (1997), the disclosure of which is incorporated by reference herein. As will be understood by one of ordinary skill in the art upon reading this disclosure, electroless plating has a very high selectivity, excellent step coverage and good via/trench filling because of the very thin seed layers formed by the electroless plating method.

In the article by Shacham-Diamand et al., three practical seeding methods for the electroless deposition of copper, which can be used with the present invention, are presented. The three practical seeding methods for the electroless deposition of copper are: (1) noble metal seeding, typically on gold, palladium or platinum; (2) copper seeding using an aluminum sacrificial layer; and (3) wet activation of surfaces using a contact displacement method. The article by Shacham-Diamand et al. demonstrates the successful use of the third method to deposit copper on Ti/TiN or TiN/AlCu at room temperature.

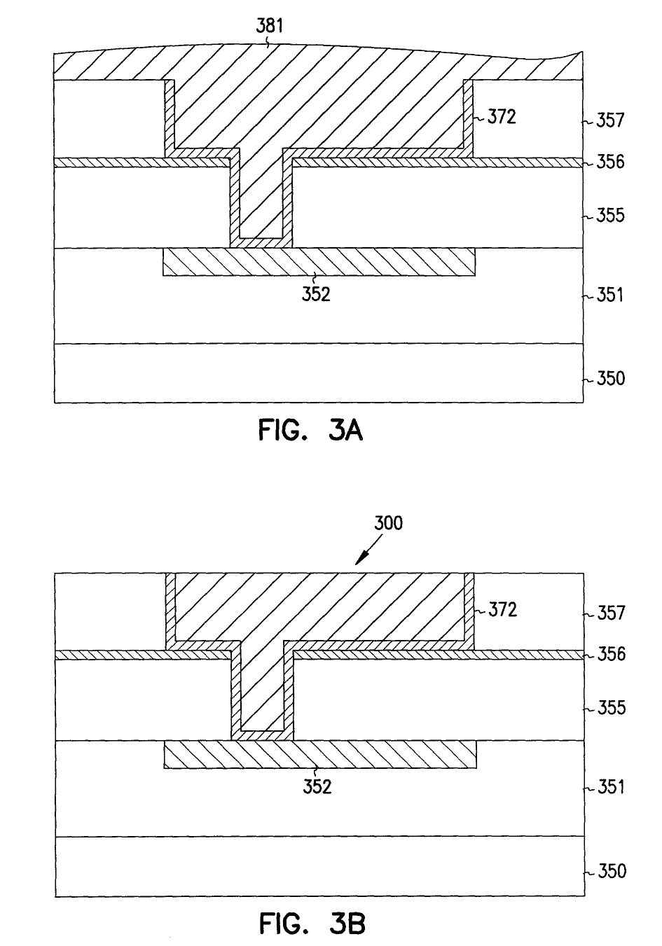

FIGS. 3A-3B are cross-sectional views illustrating a sequence of fabrication steps for forming a dual damascene copper interconnect in association with a semiconductor device in accordance with a second embodiment of the present invention. FIGS. 3A-3B are intended to cover an embodiment of the present invention which employs the above mentioned wet activation of surfaces using a contact displacement method. In the embodiment of FIG. 3A, according to the teachings of the present invention, contact displacement copper deposition is used to first selectively activate the tungsten-nitride (WN₂) material, serving as the diffusion barrier layer 372, after which selective electroless copper deposition is employed to obtain a copper layer 381. Copper deposition by contact displacement offers the advantage of room temperature processing, which in turn allows many low dielectric constant organic and/or inorganic materials to be used as the material of choice for interlayer dielectrics, such as the first and second intermetal insulating layers 355, 357.

After the deposition of the copper material 381, as shown in FIG. 3A, excess copper formed above the surface of the second insulating material 357 can be removed by either an etching or a polishing technique to form a copper dual damascene structure 300, as illustrated in FIG. 3B. In one embodiment of the present invention, chemical mechanical polishing (CMP) is used to polish away excess copper above the second insulating material 357 and the trench 367 level. In this manner, the second insulating material 357 acts as a polishing stop layer when CMP is used.

Again, as one of ordinary skill in the art will understand upon studying this invention, the above described embodiments for deposition of the copper material 381 using an electroless plating technique also helps to reduce the amount of wasted copper in the process.

Although only one copper dual damascene structure, e.g. structures 200 and 300, is shown in FIG. 2K and FIG. 3B, respectively, it will be readily apparent to those skilled in the art that in fact any number of such copper dual damascene structures may be formed on the substrate. Also, although the exemplary embodiments described above refer to the formation of copper dual damascene structures, 200 and 300, the invention is further applicable to other types of damascene structures.

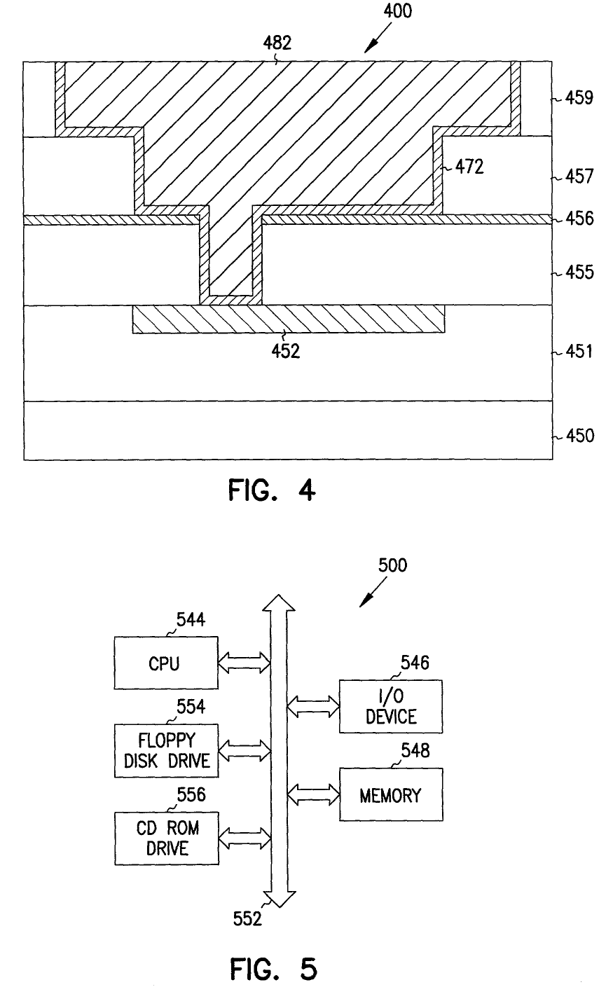

FIG. 4 thus illustrates an embodiment, according to the teachings of the present invention, for a triple damascene structure 400. The triple damascene structure 400, shown in FIG. 4, follow the same processing steps described above in connection with FIGS. 2 and 3. Thus, the triple damascene structure 400 of FIG. 4 will include a tungsten-nitride (WN₂) material, serving as a diffusion barrier layer 472 and copper 482 selectively deposited by the methods described in detail above. For example, FIG. 4 illustrates a triple damascene structure 400 with three intermetal insulating layers 455, 457, and 459 (which can comprise same or different insulating materials) formed over the substrate 450 and in which vias 465 and trenches 467 have been formed and then simultaneously filled with the selectively deposited copper 482 by the methods described above.

As one of ordinary skill in the art will understand from reading this disclosure, further steps to create a functional memory cell or other integrated circuit component having the interconnects of the present invention can be carried out. Hence, additional multilevel interconnect layers and associated dielectric layers can be formed to create operative electrical paths from any of the copper damascene structures 200, 300, and 400 to appropriate regions of a circuit integrated on a substrate.

FIG. 5 illustrates an embodiment of an electronic system 500 having such a memory cell with a copper damascene structure according to the present invention. As shown in FIG. 5, the electronic system 500 is a processor-based 544 system which includes a memory circuit 548, for example a DRAM. According to the teachings of the present invention, either the processor 544, the memory circuit 548, or both contain damascene structures, such as the copper damascene structures described in connection with FIGS. 2, 3 and 4. The electronic system 500 shown in FIG. 5 illustrates generally a computer system 500. Such a computer system 500 generally comprises a central processing unit (CPU) 544, such as a microprocessor, a digital signal processor, or other programmable digital logic devices, which communicates with an input/output (I/O) device 546 over a bus 552. The memory 548 communicates with the system 500 over bus 552.

In the case of a computer system 500, the processor-based system may include peripheral devices such as a floppy disk drive 554 and a compact disk (CD) ROM drive 556 which also communicates with CPU 544 over the bus 552. According to the teachings of the present invention, memory 548 can be constructed as an integrated circuit, which includes one or more copper damascene structures as described above in connection with FIGS. 2, 3, and 4. 100, 200, 300. In one embodiment according to the teachings of the present invention, the memory 548 and the processor, for example CPU 544, can be formed on a single chip as a single integrated circuit.

The above description and drawings are only to be considered illustrative of exemplary embodiments which achieve the features and advantages of the present invention. Modification and substitutions to specific process conditions and structures can be made without departing from the spirit and scope of the present invention. Accordingly, the invention is not to be considered as being limited by the foregoing description and drawings, but is only limited by the scope of the appended claims.

What is claimed:

1. A method of forming a copper damascene structure, comprising:
forming a first opening through a first insulating layer;
forming a second opening through a second insulating layer which is provided over the first insulating layer, the first opening being in communication with the second opening;
forming a tungsten-nitride (WN₂) layer in contact with the first and second openings; and
providing a copper layer in the first and second openings.

2. The method of claim 1, wherein the first insulating layer includes oxide material.

3. The method of claim 1, wherein the first insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

4. The method of claim 1, wherein the first insulating layer is formed by deposition to a thickness of about 2,000 to 15,000 Angstroms.

5. The method of claim 4, wherein the first insulating layer is formed by deposition to a thickness of about 6,000 to 10,000 Angstroms.

6. The method of claim 1, wherein the second insulating layer includes oxide material.

7. The method of claim 1, wherein the second insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

8. The method of claim 1, wherein the second insulating layer is formed by deposition to a thickness of about 2,000 to 15,000 Angstroms.

9. The method of claim 8, wherein the second insulating layer is formed by deposition to a thickness of about 6,000 to 10,000 Angstroms.

10. The method of claim 1, wherein the first and second insulating layers are formed of same material.

11. A method of forming a copper damascene structure, comprising:
forming a first opening through a first insulating layer;
forming a second opening through a second insulating layer which is provided over the first insulating layer, the first opening being in communication with the second opening;
forming a tungsten-nitride (WN₂) layer using atomic layer deposition such that the tungsten-nitride (WN₂) layer is in contact with the first and second openings; and
providing a copper layer in the first and second openings.

12. The method of claim 11, wherein forming a tungsten-nitride (WN₂) layer using atomic layer deposition includes forming a tungsten-nitride (WN₂) layer which has a thickness of less than five atomic layers.

13. The method of claim 11, wherein the tungsten-nitride (WN₂) layer is deposited at a temperature of about 600-800 Kelvin.

14. The method of claim 11, wherein the copper layer is selectively deposited by chemical vapor deposition.

15. The method of claim 15, wherein the copper layer is selectively deposited at a temperature of about 300° C. to about 400° C.

16. The method of claim 16, wherein the copper layer is selectively deposited in an atmosphere of pure hydrogen from the β-diketonate precursor bis(6,6,7,8,8,8-heptafluoro-2,2-dimetyl 1-3,5-octanedino) copper (II).

17. The method of claim 14, wherein the copper layer is selectively deposited in an atmosphere of pure argon from the β-diketonate precursor bis(6,6,7,8,8,8-heptafluoro-2,2-dimetyl 1-3,5-octanedino) copper (II).

18. The method of claim 11, wherein the method further includes using a chemical mechanical polishing technique to remove the tungsten-nitride (WN₂) layer from a top surface of the second insulating layer prior to providing a copper layer in the first and second openings.

19. The method of claim 11, wherein the method further includes using a chemical mechanical polishing technique to remove the copper layer from a top surface of the second insulating layer.

20. A method of forming a copper damascene structure, comprising:
forming a first opening through a first insulating layer;
forming a second opening through a second insulating layer which is provided over the first insulating layer, the first opening being in communication with the second opening;
forming a tungsten-nitride (WN₂) layer, which is less than five atomic layers thick, using atomic layer deposition such that the tungsten-nitride (WN₂) layer is in contact with the first and second openings, and wherein the tungsten-nitride (WN₂) layer is deposited at a temperature of about 600-800 Kelvin; and
providing a copper layer in the first and second openings using a selective deposition process.

21. The method of claim 20, wherein the copper layer is selectively deposited using an electroless plating technique.

22. The method of claim 20, wherein the copper layer is selectively deposited at a temperature of about 300° C. to about 400° C.

23. The method of claim 22, wherein the copper layer is selectively deposited in an atmosphere of pure hydrogen from the β-diketonate precursor bis(6,6,7,8,8,8-heptafluoro-2,2-dimetyl 1-3,5-octanedino) copper (II).

24. The method of claim 22, wherein the copper layer is selectively deposited in an atmosphere of pure argon from the β-diketonate precursor bis(6,6,7,8,8,8-heptafluoro-2,2-dimetyl 1-3,5-octanedino) copper (II).

25. The method of claim 20, wherein the method further includes using a chemical mechanical polishing technique to remove the tungsten-nitride (WN₂) layer from a top surface of the second insulating layer prior to providing a copper layer in the first and second openings.

26. The method of claim 20, wherein the method further includes using a chemical mechanical polishing technique to remove the copper layer from a top surface of the second insulating layer.

27. A method of forming a copper damascene structure, comprising:
forming a first opening through a first insulating layer;
forming a second opening through a second insulating layer which is provided over the first insulating layer, the first opening being in communication with the second opening;
forming a tungsten-nitride (WN₂) layer, which is less than five atomic layers thick, using atomic layer deposition such that the tungsten-nitride (WN₂) layer is in contact with the first and second openings, and wherein the tungsten-nitride (WN₂) layer is deposited at a temperature of about 600-800 Kelvin; and
providing a copper layer in the first and second openings using a selective chemical vapor deposition process at a temperature of about 300° C. to about 400° C.

28. The method of claim 27, wherein the copper layer is selectively deposited in an atmosphere of pure hydrogen from the β-diketonate precursor bis(6,6,7,8,8,8-heptafluoro-2,2-dimetyl 1-3,5-octanedino) copper (II).

29. The method of claim 27, wherein the copper layer is selectively deposited in an atmosphere of pure argon from the β-diketonate precursor bis(6,6,7,8,8,8-heptafluoro-2,2-dimetyl 1-3,5-octanedino) copper (II).

30. The method of claim 27, wherein the method further includes using a chemical mechanical polishing technique to remove the tungsten-nitride (WN₂) layer from a top surface of the second insulating layer prior to providing a copper layer in the first and second openings.

31. The method of claim 27, wherein the method further includes using a chemical mechanical polishing technique to remove the copper layer from a top surface of the second insulating layer.

32. A dual damascene structure, comprising:
a substrate;
a metal layer provided within the substrate;
a first insulating layer located over the substrate;
a via situated within the first insulating layer and extending to at least a portion of the metal layer, the via being lined with a tungsten-nitride (WN₂) layer and filled with a copper material;
a second insulating layer located over the first insulating layer;
a trench situated within the second insulating layer and extending to the via, the trench being lined with the tungsten-nitride (WN₂) layer and selectively filled with the copper material.

33. The dual damascene structure of claim 32, wherein the first insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

34. The dual damascene structure of claim 32, wherein the first insulating layer includes silicon dioxide.

35. The dual damascene structure of claim 32, wherein the first insulating layer has a thickness of about 2,000 to 15,000 Angstroms.

36. The dual damascene structure of claim 32, wherein the second insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

37. The dual damascene structure of claim 32, wherein the second insulating layer includes silicon dioxide.

38. The dual damascene structure of claim 32, wherein the second insulating layer has a thickness of about 2,000 to 15,000 Angstroms.

39. A dual damascene structure, comprising:
a substrate;
a metal layer provided within the substrate;
a first insulating layer located over the substrate;
a via situated within the first insulating layer and extending to at least a portion of the metal layer, the via being lined with a tungsten-nitride (WN₂) layer, wherein the tungsten-nitride (WN₂) layer has a thickness of about 500 Angstroms to about 200 Angstroms, and filled with a copper material;
a second insulating layer located over the first insulating layer;
a trench situated within the second insulating layer and extending to the via, the trench being lined with the tungsten-nitride (WN₂) layer, wherein the tungsten-nitride (WN₂) layer has a thickness of about 500 Angstroms to about 200 Angstroms, and selectively filled with the copper material.

40. The dual damascene structure of claim 39, wherein the tungsten-nitride (WN₂) layer has a thickness of about 100 Angstroms.

41. The dual damascene structure of claim 40, wherein the copper material includes copper or a copper alloy.

42. The dual damascene structure of claim 40, wherein the substrate is a semiconductor substrate.

43. The dual damascene structure of claim 40, wherein the substrate is a silicon substrate.

44. A dual damascene structure, comprising:
a substrate;
a metal layer provided within the substrate;
a first insulating layer located over the substrate;
a via situated within the first insulating layer and extending to at least a portion of the metal layer, the via being lined with a tungsten-nitride (WN₂) layer which is less than five atomic layers thick formed using atomic layer deposition at a temperature of about 600-800 Kelvin, and selectively filled with a copper material;
a second insulating layer located over the first insulating layer;
a trench situated within the second insulating layer and extending to the via, the trench being lined with the tungsten-nitride (WN₂) layer which is less than five atomic layers thick formed using atomic layer deposition at a temperature of about 600-800 Kelvin, and selectively filled with the copper material.

45. The dual damascene structure of claim 44, wherein the via and the trench being lined with a tungsten-nitride (WN₂) layer and filled with copper includes copper which is selectively deposited by chemical vapor deposition.

46. The dual damascene structure of claim 44, wherein the via and the trench being lined with a tungsten-nitride (WN₂) layer and filled with copper includes copper which is selectively deposited at a temperature of about 300° C. to about 400° C.

47. The dual damascene structure of claim 46, wherein the copper which is selectively deposited at a temperature of about 300° C. to about 400° C. includes copper which is selectively deposited in an atmosphere of pure hydrogen from the β-diketonate precursor bis(6,6,7,8,8,8-heptafluoro-2,2-dimetyl 1-3,5-octanedino) copper (II).

48. The dual damascene structure of claim 46, wherein the copper which is selectively deposited at a temperature of about 300° C. to about 400° C. includes copper which is selectively deposited in an atmosphere of pure argon from the β-diketonate precursor bis(6,6,7,8,8,8-heptafluoro-2,2-dimetyl 1-3,5-octanedino) copper (II).

49. A damascene structure, comprising:
a substrate;
a metal layer provided within the substrate;
at least one insulating layer located over the substrate; and
at least one opening situated within the at least one insulating layer and extending to at least a portion of the metal layer, the opening being lined with a tungsten-nitride (WN₂) layer formed using atomic layer deposition at a temperature of about 600-800 Kelvin, and filled with a copper material.

50. The damascene structure of claim 49, wherein the at least one insulating layer includes a material selected from the group consisting of polyimide, spin-on-polymers, flare, polyarylethers, parylene, polytetrafluoroethylene, benzocyclobutene, SILK, fluorinated silicon oxide, hydrogen silsesquioxane and NANOGLASS.

51. The damascene structure of claim 49, wherein the at least one insulating layer includes silicon dioxide.

52. The damascene structure of claim 49, wherein the at least one insulating layer has a thickness of about 2,000 to 15,0000 Angstroms.

53. The damascene structure of claim 49, wherein the tungsten-nitride (WN₂) layer has a thickness of about 50 Angstroms to about 200 Angstroms.

54. The damascene structure of claim 49, wherein the tungsten-nitride (WN₂) layer has a thickness of about 100 Angstroms.

55. The damascene structure of claim 49, wherein the copper material includes copper or a copper alloy.

56. A damascene structure, comprising:
a substrate;
a metal layer provided within the substrate;
at least one insulating layer located over the substrate;
at least one opening situated within the at least one insulating layer and extending to at least a portion of the metal layer, the opening being lined with a tungsten-nitride (WN₂) layer formed using atomic layer deposition at a temperature of about 600-800 Kelvin, and filled with a copper material; and
wherein the opening being lined with a tungsten-nitride (WN₂) layer and filled with copper includes copper which is selectively deposited at a temperature of about 300° C. to about 400° C.

57. The damascene structure of claim 56, wherein the copper which is selectively deposited at a temperature of about 300° C. to about 400° C. includes copper which is selectively deposited in an atmosphere of pure hydrogen from the β-diketonate precursor bis(6,6,7,8,8,8-heptafluoro-2,2-dimetyl 1-3,5-octanedino) copper (II).

58. The damascene structure of claim 56, wherein the copper which is selectively deposited at a temperature of about 300° C. to about 400° C. includes copper which is selectively deposited in an atmosphere of pure argon from the β-diketonate precursor bis(6,6,7,8,8,8-heptafluoro-2,2-dimetyl 1-3,5-octanedino) copper (II).

59. The damascene structure of claim 56, wherein the substrate is a semiconductor substrate.

60. The damascene structure of claim 56, wherein the substrate is a silicon substrate.

61. An electronic system comprising:
a processor; and
an integrated circuit coupled to the processor, at least one of the processor and integrated circuit including a damascene structure, the damascene structure comprising a metal layer over a substrate, at least one insulating layer located over the metal layer, and at least one opening situated within the at least one insulating layer and extending to at least a portion of the metal layer, the opening being lined with a tungsten-nitride (WN₂) layer and filled with copper.

62. The electronic system of claim 61, wherein the processor and the integrated circuit are integrated on the same chip.

63. The electronic system of claim 61, wherein the tungsten-nitride (WN₂) layer has a thickness of about 500 Angstroms to about 200 Angstroms.

64. The electronic system of claim 63, wherein the tungsten-nitride (WN₂) layer has a thickness of about 100 Angstroms.

65. The electronic system of claim 61, wherein the tungsten-nitride (WN₂) layer includes a is deposited at a temperature of about 600-800 Kelvin.

66. The electronic system of claim 61, wherein the opening being lined with a tungsten-nitride (WN₂) layer and filled with copper includes copper which is selectively deposited by chemical vapor deposition.

67. The electronic system of claim 61, wherein the opening being lined with a tungsten-nitride (WN₂) layer and filled with copper includes copper which is selectively deposited at a temperature of about 300° C. to about 400° C.

68. The electronic system of claim 67, wherein the copper which is selectively deposited at a temperature of about 300° C. to about 400° C. includes copper which is selectively deposited in an atmosphere of pure hydrogen from the β-diketonate precursor bis(6,6,7,8,8,8-heptafluoro-2,2-dimetyl 1-3,5-octanedino) copper (II).

69. The electronic system of claim 67, wherein the copper which is selectively deposited at a temperature of about 300° C. to about 400° C. includes copper which is selectively deposited in an atmosphere of pure argon from the β-diketonate precursor bis(6,6,7,8,8,8-heptafluoro-2,2-dimetyl 1-3,5-octanedino) copper (II).
